(19) United States
(12) Patent Application Publication
(10) Pub. No.: US 2026/0362857 A1
(43) Pub. Date: Nov. 12, 2026

(54) LED PACKAGING PROCESS

(71) Applicant: Manlux Technologies Inc., San Meteo, CA (US)

(72) Inventors: Kin wah Man, London (GB); CHUN HOCK YEO, KOTA SAMARAHAN SARAWAK (MY); Baiyan Chen, SHENZHEN (CN)

(21) Appl. No.: 19/203,193

(22) Filed: May 9, 2025

(51) Int. Cl. H10H 20/85; H10H 20/01; H10H 20/851; H10H 20/853

(52) U.S. Cl. CPC H10H 20/8508; H10H 20/0361; H10H 20/0362; H10H 20/8514; H10H 20/853

(57) ABSTRACT

Disclosed in the present disclosure is an LED packaging process, which relates to the technical field of LEDs. The process includes the following steps: performing planarization treatment on a ceramic substrate to ensure surface flatness and provide a foundation for subsequent processes; arranging a dam on the ceramic substrate, where the inner side of the dam has an inclination angle of 50±5°, in which this angular design enhances light extraction efficiency of the chip and reduces optical loss; performing color adjustment after completing dam arrangement; and performing a mold-top-ball-head process after completing the color adjustment process to form a complete LED packaging structure. The present disclosure optimizes light extraction efficiency through the dam structure and inclination angle design, while improving luminous efficacy and uniformity of LEDs by combining multiple color adjustment processes.

### TECHNICAL FIELD

The present disclosure relates to the technical field of LEDs, and in particular to an LED packaging process.

### BACKGROUND

LED (Light Emitting Diode), as a high-efficiency and energy-saving light source, has been widely applied in fields such as lighting and display. In LED packaging processes, how to improve light extraction efficiency remains a critical technical challenge. Conventional LED packaging structures typically adopt planar substrates, where light extraction effects are constrained. Furthermore, existing color adjustment processes (e.g., dispensing, powder spraying, film laminating) suffer from uneven luminous efficacy and process complexity in practical applications. Therefore, there is a demand for a novel packaging structure and process to optimize light extraction effects while simplifying process flows.

### SUMMARY

To address the deficiencies of the prior art, the objective of the present disclosure is to provide an LED packaging process that optimizes light extraction effects through dam structure and inclination angle design, while enhancing luminous efficacy and uniformity of LEDs by integrating multiple color adjustment processes.

To achieve the aforementioned objective, the technical solution of the present disclosure is implemented as follows: An LED packaging process includes the following steps:
1. ceramic substrate pretreatment: performing planarization treatment on a ceramic substrate at shadow portion A to ensure surface flatness, providing a foundation for subsequent processes.
2. dam structure design: arranging a dam on the ceramic substrate, where an inner side of the dam has an inclination angle of 50±5°, in which this angular design enhances light extraction efficiency of a chip and reduces optical loss.
3. color adjustment process: performing color adjustment, after completing dam arrangement.

In some implementations, the LED packaging process further includes a mold-top-ball-head process, where after completing the color adjustment process, performing the mold-top-ball-head process to form a complete LED packaging structure. The ball head is adjustable to different angles.

In some implementations, the color adjustment employs any one of the following processes:
conventional dispensing process: coating phosphor gel uniformly on the inner side of the dam through dispensing equipment.
powder spraying process: spraying phosphor powder on the inner side of the dam to form a uniform phosphor layer.
film laminating process: adhering a phosphor film to the inner side of the dam to achieve color adjustment.

In some implementations, the dam adopts circular, square cup, or elliptical shapes.

Beneficial effects of the present disclosure: the dam structure and inclination angle design according to the present disclosure significantly improves light extraction efficiency of LED chips. The employment of multiple color adjustment processes (e.g., dispensing, powder spraying, film laminating) allows selection of the most suitable process according to requirements, enhancing production flexibility and uniformity of luminous efficacy. The planarization treatment of the ceramic substrate ensures surface flatness, providing a robust foundation for subsequent processes. The mold-top-ball-head process further optimizes the packaging structure, improving LED reliability and luminous efficacy.

### BRIEF DESCRIPTION OF THE DRAWINGS

The present disclosure will be described in detail below with reference to the attached drawings and specific embodiments:

FIG. 1 shows a front-side dam schematic diagram of the substrate of the present disclosure;

FIG. 2 shows a bottom view of FIG. 1;

FIG. 3 shows front-side and back-side schematic views of the substrate of the present disclosure;

FIG. 4 shows front-side and ball head schematic views of the substrate of the present disclosure;

FIG. 5 shows a schematic view of the ball head of the present disclosure.

### DETAILED DESCRIPTION

To facilitate a clear understanding of the technical means, creative features, objectives, and effects achieved by the present disclosure, specific embodiments are further described below in conjunction with practical implementations.

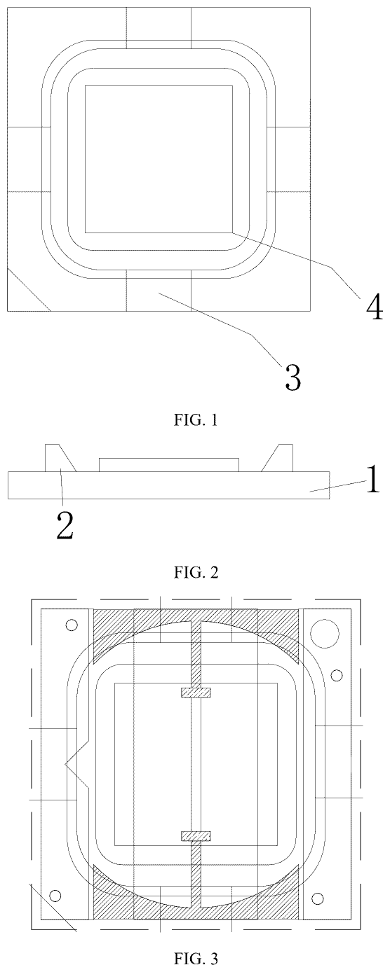

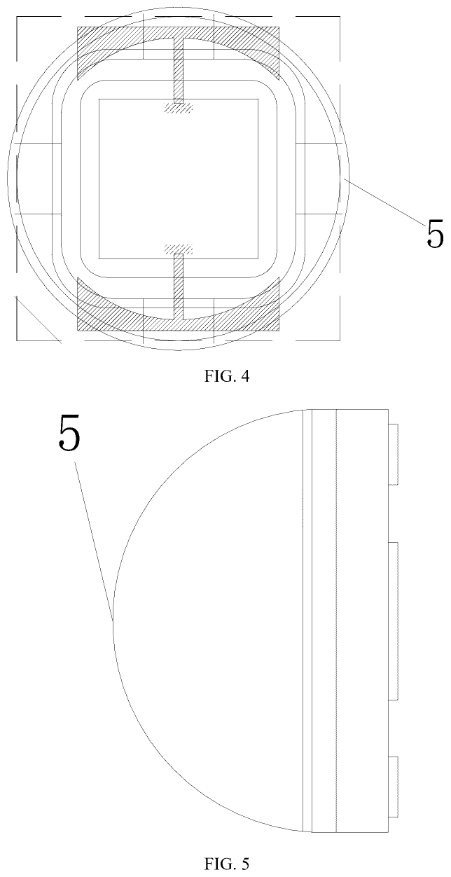

Referring to FIGS. 1-5, this embodiment adopts the following technical solution: an LED packaging process includes the following steps:
1. Ceramic substrate pretreatment: performing planarization treatment on a ceramic substrate 1 to ensure surface flatness, providing a foundation for subsequent processes. Middles of four edges at the front side of the ceramic substrate 1 are provided with injection molding holes 3, and the center of the ceramic substrate 1 is provided with a spacer 4.
2. Dam structure design: arranging a dam 2 on the ceramic substrate, where an inner side of the dam 2 has an inclination angle of 50±5°, in which this angular design enhances light extraction efficiency of a chip and reduces optical loss.
3. Color adjustment process: performing color adjustment, after completing dam arrangement. The color adjustment employs any one of following processes:
   3.1 Conventional dispensing process: coating phosphor gel uniformly on the inner side of the dam through dispensing equipment.
   3.2 Powder spraying process: spraying phosphor powder on the inner side of the dam to form a uniform phosphor layer.
   3.3 Film laminating process: adhering a phosphor film to the inner side of the dam to achieve color adjustment.

The LED packaging process further includes a mold-top-ball-head process, where after completing the color adjustment process, performing the mold-top-ball-head process to form a complete LED packaging structure. The ball head is adjustable to different angles.

In this embodiment, a ceramic substrate is selected, and planarization treatment is performed on the ceramic substrate to ensure surface flatness. A dam is arranged on the ceramic substrate, where the inner side of the dam has an inclination angle of 50±5°. A dispensing, powder spraying, or film laminating process is selected for color adjustment according to requirements. After completing color adjustment, the mold-top-ball-head process is performed to form a complete LED packaging structure.

In this embodiment, the pretreatment and planarization treatment of the ceramic substrate first ensure surface flatness, providing a stable foundation for subsequent processes; secondly, the 50±5° inclination angle design on the inner side of the dam significantly enhances light extraction efficiency of the LED chip and reduces optical loss; additionally, the employment of multiple color adjustment processes such as dispensing, powder spraying, or film laminating not only improves production flexibility but also enables selection of the most suitable process according to requirements, ensuring uniformity and consistency of luminous efficacy; finally, the mold-top-ball-head process further optimizes the packaging structure, improving LED reliability and luminous efficacy. The overall process is streamlined and efficient, suitable for mass production, and exhibits broad application prospects.

The above description illustrates and elaborates the fundamental principles, primary features, and advantages of the present disclosure. Those skilled in the art should understand that the present disclosure is not limited by the aforementioned embodiments, which and the descriptions in the specification merely explain the principles of the disclosure. Without departing from the spirit and scope of the present disclosure, various modifications and improvements may be made, all of which fall within the scope of the claimed invention. The protection scope of the present disclosure is defined by the appended claims and their equivalents.

What is claimed is:

1. An LED packaging process, comprising following steps:
(1) ceramic substrate pretreatment: performing planarization treatment on a ceramic substrate to ensure surface flatness, providing a foundation for subsequent processes;
(2) dam structure design: arranging a dam on the ceramic substrate, where an inner side of the dam has an inclination angle of 50±5°, in which this angular design enhances light extraction efficiency of a chip and reduces optical loss; and
(3) color adjustment process: performing color adjustment, after completing dam arrangement.

2. The LED packaging process according to claim 1, further comprising a mold-top-ball-head process, where after completing the color adjustment process, performing the mold-top-ball-head process to form a complete LED packaging structure.

3. The LED packaging process according to claim 1, wherein the color adjustment employs any one of following processes:
conventional dispensing process: coating phosphor gel uniformly on the inner side of the dam through dispensing equipment;
powder spraying process: spraying phosphor powder on the inner side of the dam to form a uniform phosphor layer;
film laminating process: adhering a phosphor film to the inner side of the dam to achieve color adjustment.

4. The LED packaging process according to claim 1, wherein the dam adopts circular, square cup, or elliptical shapes.

5. The LED packaging process according to claim 2, wherein the ball head is adjustable to different angles.
